(19) United States
(12) Patent Application Publication
(10) Pub. No.: US 2020/0357905 A1
(43) Pub. Date: Nov. 12, 2020

(54) III-NITRIDE TRANSISTOR DEVICE WITH A THIN BARRIER

(71) Applicant: Cambridge Electronics Inc., Cambridge, MA (US)

(72) Inventor: BIN LU, WATERTOWN, MA (US)

(73) Assignee: Cambridge Electronics Inc., Cambridge, MA (US)

(21) Appl. No.: 16/869,180

(22) Filed: May 7, 2020

Related U.S. Application Data
(60) Provisional application No. 62/845,050, filed on May 8, 2019.

(51) Int. Cl. H01L 29/778; H01L 29/20; H01L 29/205; H01L 29/66; H01L 29/417

(52) U.S. Cl. CPC H01L 29/7783; H01L 29/2003; H01L 29/41725; H01L 29/66462; H01L 29/205

(57) ABSTRACT

An improved semiconductor structure includes a substrate, a buffer layer disposed on a top surface of the substrate, a channel layer disposed on a top surface of the buffer layer, a barrier layer disposed on a top surface of the channel layer, an etch-stop layer disposed on a top surface area of the barrier layer, a cap-layer disposed on a top surface area of the etch-stop layer, a source contact disposed on a first area of the barrier layer, a drain contact disposed on a second area of the barrier layer, a gate contact disposed on the cap layer between the source contact and the drain contact, and a dielectric layer disposed on areas of the etch-stop layer between the source contact and the gate contact and between the drain contact and the gate contact, respectively. The etch-stop layer is disposed on an area of the top surface of the barrier layer between the first area and the second area.

### CROSS REFERENCE TO RELATED CO-PENDING APPLICATIONS

This application claims the benefit of U.S. provisional application Ser. No. 62/845,050 filed May 8, 2019 and entitled “THIN BARRIER III NITRIDE TRANSISTOR”, the contents of which are expressly incorporated herein by reference.

### FIELD OF THE INVENTION

The present invention relates to a III-Nitride transistor device, and more particularly to a III-Nitride transistor device that includes a thin barrier layer.

### BACKGROUND OF THE INVENTION

Referring to FIG. 1, a typical III-Nitride semiconductor transistor structure 80 includes a substrate 82, a buffer layer 83 on top of the substrate, a GaN channel layer 84 on top of the buffer layer and an AlGaN barrier layer 86 on top of the channel layer 84. The substrate 82 is usually SiC, sapphire, Si or free-standing GaN semiconductors. A nucleation layer exists between the buffer layer 83 and the substrate 82. The AlGaN barrier layer 86 has a wider band-gap than the GaN channel layer 84. A p-GaN layer 88 is located on top of the AlGaN barrier layer 86 and underneath the gate electrode 89. The p-GaN layer 88 is used to realize a normally-off transistor [1].

In this structure 80, the thickness of the AlGaN barrier layer 86 is typically around 15 nm and the thickness of the p-GaN layer 88 is over 70 nm. Transistor structure 80 has the drawbacks of low gate breakdown voltage, low current density and difficulty in forming ohmic contacts.

Accordingly, there is a need for a new transistor structures that overcomes the drawbacks of the conventional device structure 80.

### SUMMARY OF THE INVENTION

In general, in one aspect, the invention features a semiconductor structure including a substrate, a buffer layer disposed on a top surface of the substrate, a channel layer disposed on a top surface of the buffer layer, a barrier layer disposed on a top surface of the channel layer, an etch-stop layer disposed on a top surface area of the barrier layer, a cap-layer disposed on a top surface area of the etch-stop layer, a source contact disposed on a first area of the barrier layer, a drain contact disposed on a second area of the barrier layer, a gate contact disposed on the cap-layer and between the source contact and the drain contact, a dielectric layer disposed on areas of the etch-stop layer between the source contact and the gate contact and between the drain contact and the gate contact, respectively. The etch-stop layer is disposed on an area of the top surface of the barrier layer between the first area and the second area.

Implementations of this aspect of the invention may include one or more of the following features. The semiconductor structure further includes a gate dielectric layer disposed between a bottom surface of the gate contact and the top surface of the cap-layer. The buffer layer comprises a first III-nitride semiconductor, the channel layer comprises a second III-nitride semiconductor, the barrier layer comprises a third III-nitride semiconductor, the etch-stop layer comprises a fourth III-nitride semiconductor, and the cap layer comprises a fifth III-nitride semiconductor. The first, second, third, fourth, and fifth III-nitride semiconductors comprise one of AlGaN, AlN, GaN, InAlN, or combinations thereof. The third III-nitride semiconductor comprises a wider band-gap than the second III-nitride semiconductor. The third III-nitride semiconductor comprises one of AlGaN, or InAlN and wherein the AlGaN, or InAlN comprise an Aluminum composition in the range of zero and 35%. The barrier layer has a thickness in the range of 0.2 nm and 20 nm. The fourth III-nitride semiconductor comprises a higher Aluminum composition than the third III-nitride semiconductor. The etch-stop layer has a thickness in the range of 0.25 nm and 5 nm. The fifth III-nitride semiconductor comprises one of Mg-doped GaN or Mg-doped AlGaN, or Mg-doped InGaN with doping density in the range of 1E17/cm³ and 1E21/cm³. The fifth III-nitride semiconductor comprises InGaN having an Indium composition less than 30%. The cap-layer comprises a thickness in the range of 1 nm and 70 nm. The gate contact comprises one of Ni, Ti, TiN, W, WN, Pt, polysilicon, a conductive material, or combinations thereof. The dielectric layer comprises one of SiₓN_{y}, SiO₂, SiOₓN_{y}, Al₂O₃, or any other dielectric that is configured to induce electrons in the channel layer at an interface between the barrier layer and the channel layer underneath the dielectric layer. The source and drain contacts comprise one of Ti, Al, TiN, W, WN, Ni, Au, Mo, a conductive material, or combinations thereof. The source and the drain contacts are configured to form ohmic contacts to the channel layer though first and second recesses formed in the dielectric layer, respectively. A bottom surface of the source contact and a bottom surface of the drain contact are in contact with the barrier layer. A bottom surface of the source contact and a bottom surface of the drain contact are in contact with the etch-stop layer. A bottom surface of the source contact and a bottom surface of the drain contact are in contact with the channel layer. A first portion of a bottom surface of the source contact and a first portion of a bottom surface of the drain contact are in contact with the etch-stop layer and a second portion of the bottom surface of the source contact and a second portion of the bottom surface of the drain contact are in contact with the barrier layer. A first portion of a bottom surface of the source contact and a first portion of a bottom surface of the drain contact are in contact with the dielectric layer and a second portion of the bottom surface of the source contact and a second portion of the bottom surface of the drain contact are in contact with the barrier layer. The substrate comprises one of SiC, sapphire, free-standing GaN, polycrystalline AlN, or a multi-layer substrate. The gate contact is wider than the cap-layer. The gate dielectric layer is non-continuous. The semiconductor structure further includes a spacer layer disposed between the barrier layer and the etch-stop layer. A bottom surface of the source contact and a bottom surface of the drain contact are in contact with the spacer layer. A first portion of a bottom surface of the source contact and a first portion of a bottom surface of the drain contact are in contact with the spacer layer and a second portion of the bottom surface of the source contact and a second portion of the bottom surface of the drain contact are in contact with the barrier layer.

In general, in another aspect, the invention features a method for forming a semiconductor structure including the following. First, providing a substrate, then depositing a buffer layer on a top surface of the substrate, then depositing a channel layer on a top surface of the buffer layer, then depositing a barrier layer on a top surface of the channel layer, then depositing an etch-stop layer on a top surface area of the barrier layer, then depositing a cap-layer on a top surface area of the etch-stop layer, then forming a source contact on a first area of the barrier layer, then forming a drain contact on a second area of the barrier layer, then forming a gate contact on the cap-layer between the source contact and the drain contact, and then depositing a dielectric layer on areas of the etch-stop layer between the source contact and the gate contact and between the drain contact and the gate contact. The etch-stop layer is deposited on an area of the top surface of the barrier layer between the first area and the second area. The method further includes depositing a spacer layer on a top surface of the barrier layer. The source contact and the drain contact are formed by first forming first and second recesses into the dielectric layer, then stopping on the etch-stop layer, then removing the etch-stop layer in the recesses to expose the barrier layer, and then depositing metal into the first and second recesses to form the source contact and the drain contact, respectively. The dielectric layer covers the etch-stop layer where the cap-layer is absent.

Among the advantages of this invention may be one or more of the following. The etch-stop layer 112 protects the barrier layer 106 from damages when etching the cap-layer 108.

The details of one or more embodiments of the invention are set forth in the accompanying drawings and description below. Other features, objects and advantages of the invention will be apparent from the following description of the preferred embodiments, the drawings and from the claims.

### BRIEF DESCRIPTION OF THE DRAWINGS

Referring to the figures, wherein like numerals represent like parts throughout the several views:

FIG. 1 is a schematic diagram of a typical III-Nitride semiconductor transistor structure;

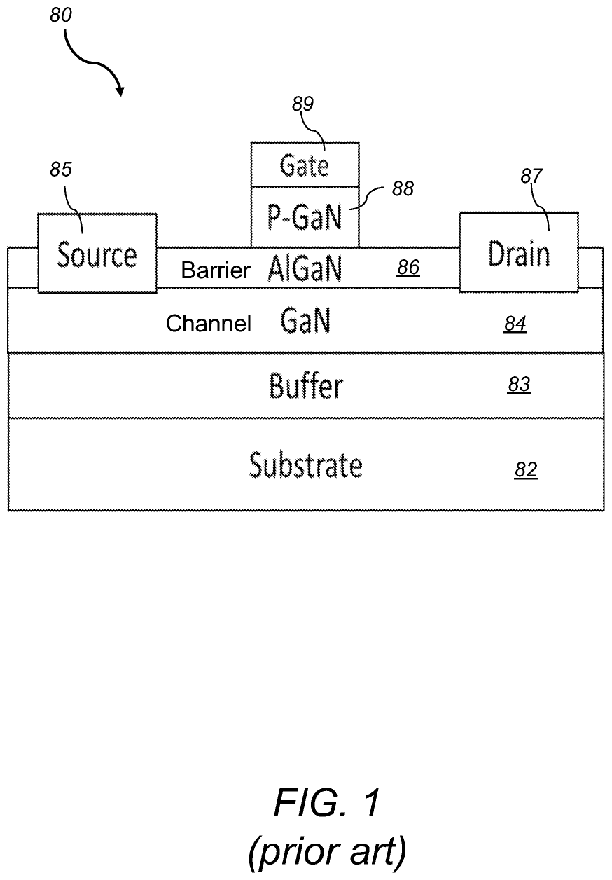

FIG. 2 is a schematic diagram of a III-Nitride semiconductor transistor structure, according to this invention;

FIG. 3 is a schematic diagram of another III-Nitride semiconductor transistor structure, according to this invention;

FIG. 4 is a flow diagram of a method for semiconductor processing of the III-Nitride semiconductor transistor structure, according to this invention;

FIG. 5 is a schematic diagram of another III-Nitride semiconductor transistor structure, according to this invention;

FIG. 6 is a schematic diagram of yet another III-Nitride semiconductor transistor structure, according to this invention;

FIG. 7 is a schematic diagram of yet another III-Nitride semiconductor transistor structure, according to this invention;

FIG. 8 is a schematic diagram of yet another III-Nitride semiconductor transistor structure, according to this invention; and

FIG. 9 is a schematic diagram of yet another III-Nitride semiconductor transistor structure, according to this invention.

### DETAILED DESCRIPTION OF THE INVENTION

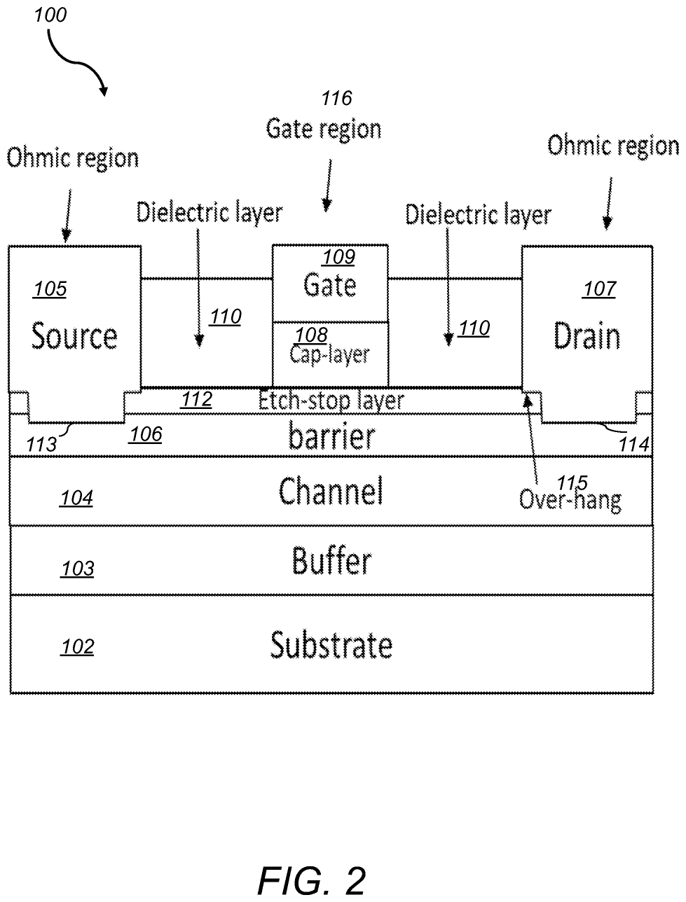

Referring to FIG. 2, a III-Nitride semiconductor transistor structure 100, according to this invention, includes a substrate 102, a buffer layer 103 on top of the substrate 102, a channel layer 104 on top of the buffer layer103, a thin barrier layer 106 on top of the channel layer 104, an etch-stop layer 112 on top of the barrier layer 106, a dielectric layer 110, a cap-layer 108, a gate 109, a source 105 and a drain 107. The substrate 102 is made of SiC, sapphire, Si, free-standing GaN or any other substrate that includes multiple layers including polycrystalline AlN. A nucleation layer is located between the buffer layer 103 and the top surface of the substrate 102. The buffer layer 103 is made of III-nitride semiconductors, such as AlGaN, AlN, GaN or a combination of them. The channel layer 104 is made of III-nitride semiconductors, such as AlGaN or GaN, where GaN is preferred. The material of the barrier layer 106 has a wider band-gap than the material of the channel layer 104. In one example, the barrier layer 106 is made of III-nitride semiconductors such as AlGaN or InAlN, where the Al composition is larger than zero and preferably less than 35%. The thickness of the barrier layer is between 0.2 nm and 20 nm. A thin barrier layer, such as less than 10 nm, is preferred, making it easier to form ohmic contacts. Etch-stop layer 112 is located on top of the barrier layer 106, and the cap-layer 108 is located on top of the etch-stop layer 112 in the gate region and underneath the gate 109. The material for the etch-stop layer 112 has a higher Al composition than the material for the barrier layer 106. The etch-stop layer 112 has a thickness between 0.25 nm and 5 nm. In one example, the etch-stop layer 112 is an AlN layer with a thickness of 1 nm. The etch-stop layer 112 protects the barrier layer 106 from damages during the etching of the cap-layer 108. The etching of the cap-layer 108 is selective over the etch-stop layer 112. The cap-layer 108 is made of III-nitride semiconductors. In one example, the cap-layer 108 includes Mg-doped GaN or AlGaN with doping density between 1E17/cm³ and 1E21/cm³. In another example, the cap-layer 108 includes InGaN with In composition less than 30%. The cap-layer 108 has a thickness between 1 nm and 70 nm. It is preferred that in the case of an InGaN based cap-layer the thickness is less than 10 nm. The cap-layer 108 is absent outside the gate region.

As was mentioned above, the gate electrode 109 is formed over the cap-layer 108. The gate electrode 109 is made of materials such as Ni, Ti, TiN, W, WN, Pt, polysilicon and any other suitable conductive material and their combinations.

Dielectric layer 110 is located over the etch-stop layer 112 outside the gate region 116 where the cap-layer 108 is absent, as shown in FIG. 2. The dielectric layer 110 covers at least a portion of the areas between the source 105 and gate 109 electrodes and between the drain 107 and gate 109 electrodes. The dielectric layer 110 is made of a material selected from SiₓN_{y}, SiO₂, SiOₓN_{y}, Al₂O₃, and any other suitable dielectric that induces electrons in the channel layer 104 at the interface between the barrier layer 106 and the channel layer 104 underneath the dielectric layer 110.

The source 105 and drain 107 electrodes are on either side of the gate 109 electrode as shown in FIG. 2. The source 105 and drain 107 electrodes are made of materials including one of Ti, Al, TiN, W, WN, Ni, Au, Mo, combinations thereof and any other suitable conductive material. The source 105 and drain 107 electrodes form ohmic contacts to the channel layer 104 underneath through recesses into the dielectric layer 110. In one example, the bottoms of the source 105 and drain 107 electrodes are in contact with the barrier layer 106 through recesses 113, 114 in the etch-stop layer 112, respectively, as shown in FIG. 2. In other embodiments, the bottoms of the source 105 and drain 107 electrodes are deposited on top of the etch-stop layer 112, or on the top surface of the barrier layer 106, or in the barrier layer 106 or below the bottom of the barrier layer 106 in contact with the channel layer 104. In another example, the source 105 and drain 107 electrodes have an over-hang region 115 contacting the etch-stop layer 112 while the bottoms of the source 105 and drain 107 electrodes contacting the barrier layer 106 as shown in FIG. 2. In yet another example, the source 105 and drain 107 electrodes have an over-hang 115 on top of the dielectric layer 110.

The transistor shown in FIG. 2 can be either a normally-on transistor with electrons in the channel layer 104 underneath the gate 109 connecting the source 105 and drain 107 when the gate 109 electrode is not biased, or a normally-off transistor with the electrons absent from the channel layer 104 underneath the gate 109 when the gate 109 electrode is not biased.

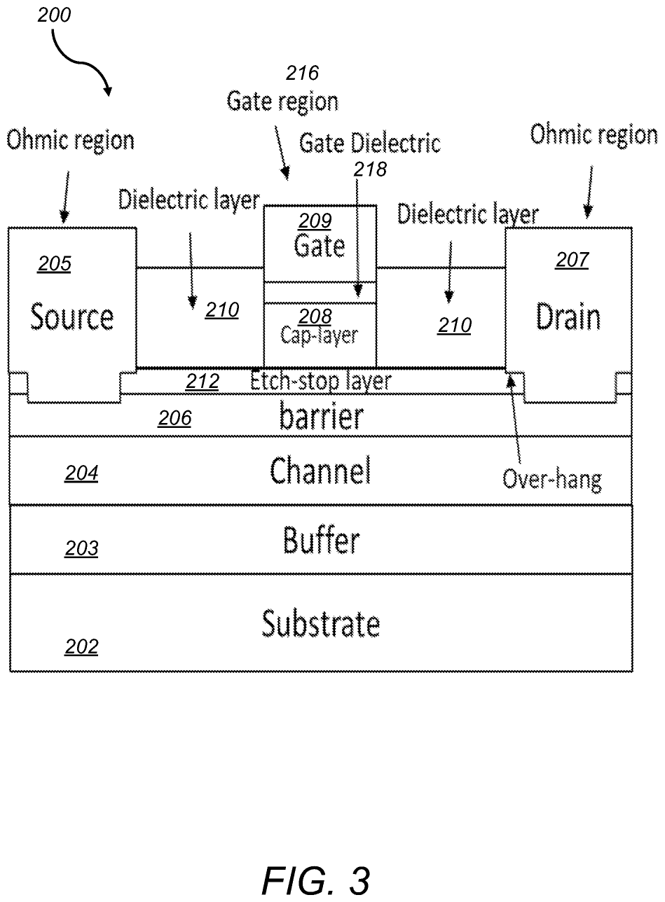

Referring to FIG. 3, a III-Nitride semiconductor transistor structure 200, according to this invention, includes a substrate 202, a buffer layer 203 on top of the substrate 202, a channel layer 204 on top of the buffer layer 203, a thin barrier layer 206 on top of the channel layer 204, an etch-stop layer 212 on top of the barrier layer 206, a dielectric layer 210, a cap-layer 208, a gate 209, a source 205 and a drain 207. In this embodiment 200, a gate dielectric layer 218 is formed between the gate electrode 209 and the cap-layer 208. The gate dielectric layer 218 is made of a dielectric materials such as SiₓN_{y}, SiO₂, SiₓO_{y}N_{z}, Al₂O₃ or any other suitable dielectric material or a combination of them. Additional passivation dielectric and field plate structures can be applied to the devices shown in FIG. 2 and FIG. 3.

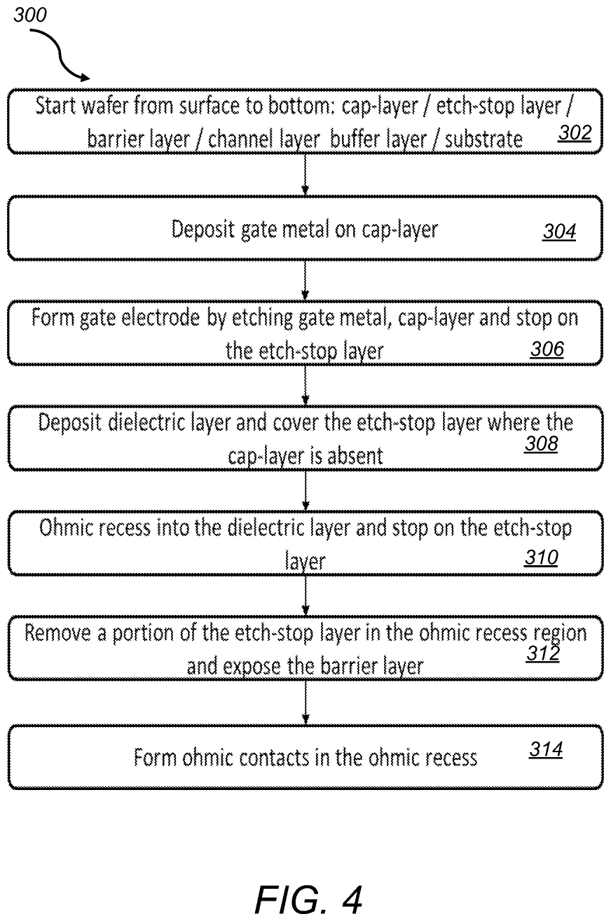

Referring to FIG. 4, a method 300 for fabricating the transistor structures 100, 200 of this invention includes the following process steps. First, the wafer is formed starting from top to bottom (302) and including forming the cap-layer 108, etch-stop layer 112, barrier layer 106, channel layer 104, buffer layer 103, and substrate 102. Next, depositing a gate metal on the cap-layer 108 (304). Next forming the gate electrode 109 by etching the gate metal, cap-layer 108 and stopping at the etch-stop layer 112 (306). Next, depositing the dielectric layer 110 and covering the etch-stop layer 112 where the cap-layer 108 is absent (308). Next, forming ohmic recesses into the dielectric layer 110 and stopping on the etch-stop layer 112 (310). Next, removing a portion of the etch-stop layer 112 in the ohmic recess region and exposing the barrier layer 106 (312). Finally, forming the ohmic contacts 105, 107 in the ohmic recesses (314). The sequence of forming the gate, 109 source 105 and drain 107 electrodes can be changed. Additional process steps not shown here include depositing additional dielectric layers, forming of field plates and interconnections, among others.

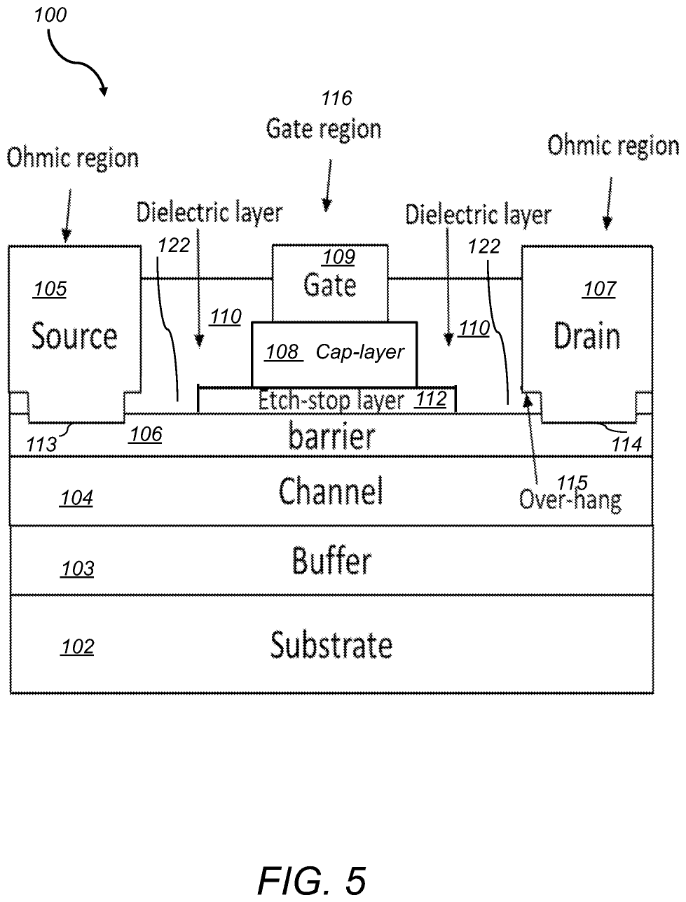

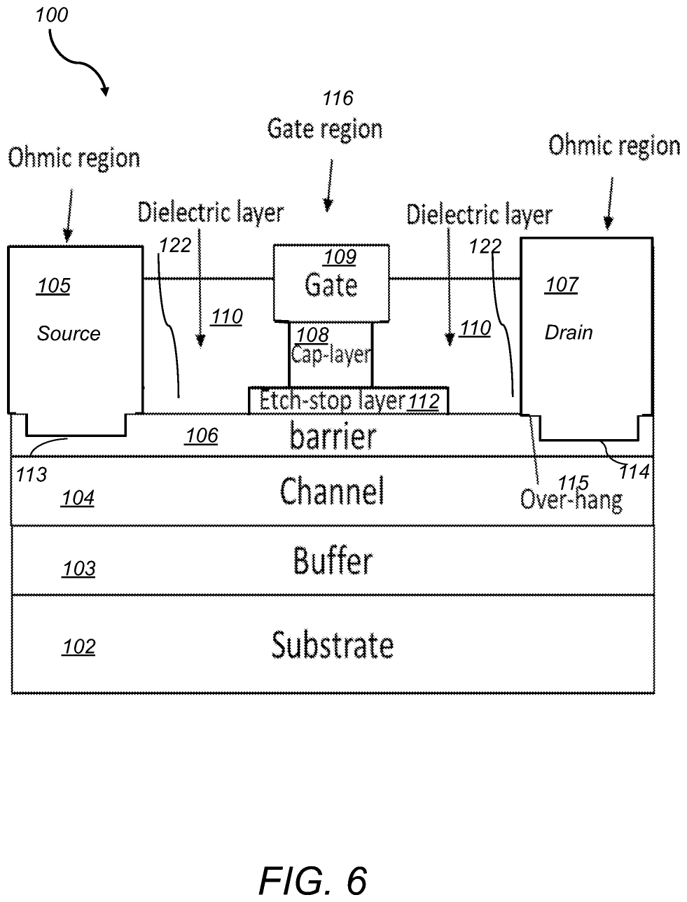

Other embodiments include one or more of the following. In one example, the cap-layer 108 has a wider width than the gate 109 and extends past the edges of gate 109, as shown in FIG. 5. In other examples, the cap-layer 108 has a narrower width than the gate 109 and does not extend to the edges of gate 109, as shown in FIG. 6. In some cases, the etch-stop layer 112 can be removed selectively over the barrier layer 106, in areas 122 outside of the gate region 116, as shown in FIG. 5 and FIG. 6. In one example, the source 105 and drain 107 electrodes have an over-hang region 115 contacting the dielectric layer 110 while the bottoms of the source 105 and drain 107 electrodes are located within the barrier layer 106, as shown in FIG. 5. In another example, the source 105 and drain 107 electrodes have an over-hang region 115 contacting the top surface of the barrier layer 106 while the bottoms of the source 105 and drain 107 electrodes are located within the barrier layer 106 as shown in FIG. 6.

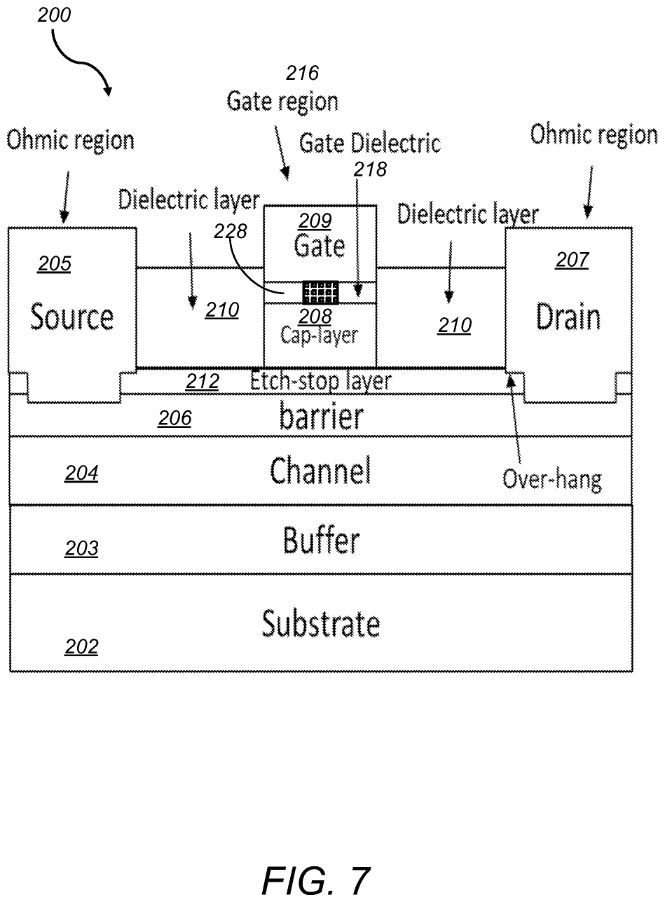

In another example, the gate dielectric layer 218 may be a non-continuous layer that includes separate areas 228, as shown in FIG. 7. Areas 228 may be arranged on a plane extending perpendicular to the cross-sectional plane shown in FIG. 7, and they may be filled with gate material.

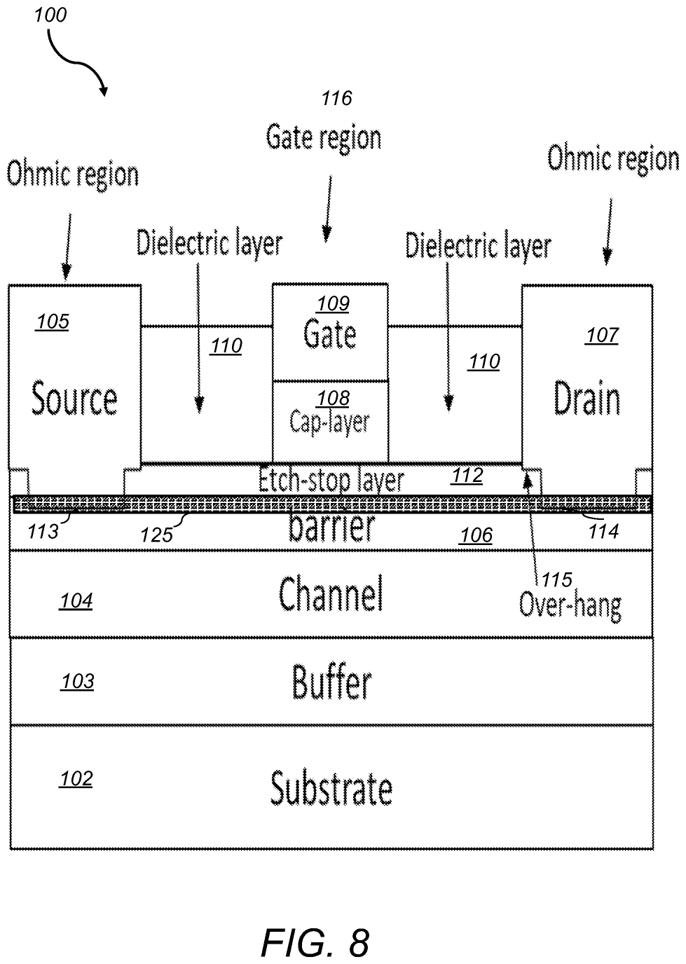

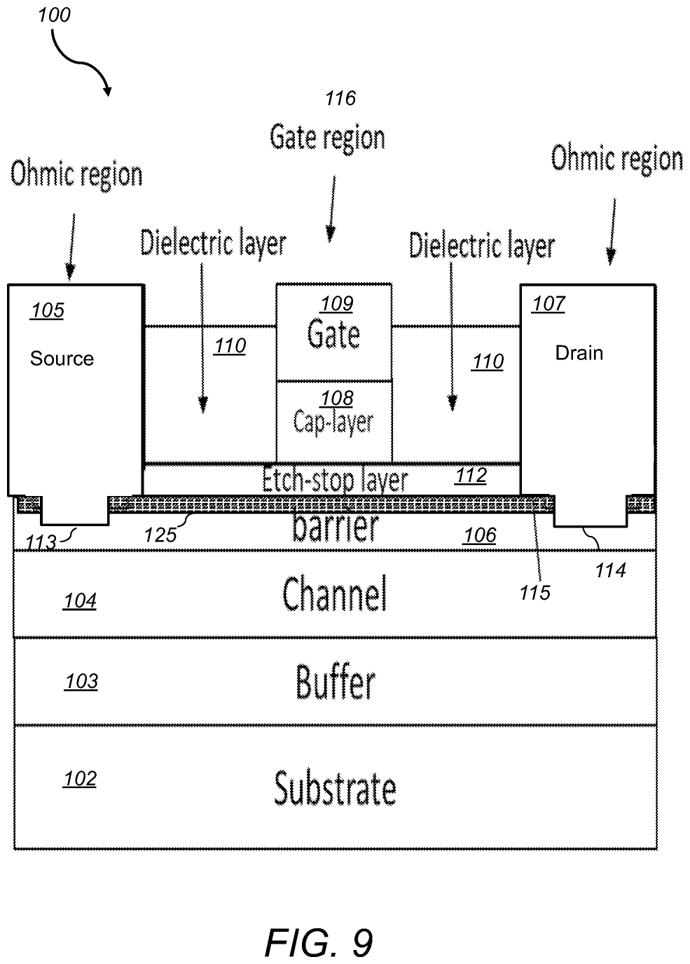

In another example, a spacer layer 125 is disposed between the barrier layer 106 and the etch-stop layer 112, as shown in FIG. 8. The spacer layer 125 is made of another III-Nitride semiconductor material that has lower Al percentage than the etch-stop layer. 112 In one example, the spacer layer 125 is made of GaN. The thickness of the spacer layer 125 is between 0.5 nm and 50 nm, preferably less than 5 nm. In this example, the etch-stop layer 112 is shown to extend outside of the gate region 116. In other examples, the etch-stop layer 112 extends only to the ends of the gate region 116. The purpose of having the spacer layer 125 is to provide the ability to selectively remove the etch-stop layer 112 outside of the gate region 116 relative to the spacer layer 125, after the removal of the cap-layer 108 (pGaN) outside of the gate region 116. In this example, the source 105 and drain 107 electrodes have an over-hang region 115 contacting the top surface of the etch-stop layer 112 while the bottoms of the source 105 and drain 107 electrodes are located within the spacer layer 125 and in contact with the top surface of the barrier layer 106, as shown in FIG. 8. In another example, the source 105 and drain 107 electrodes have an over-hang region 115 contacting the top surface of the spacer layer 125 while the bottoms of the source 105 and drain 107 electrodes are located within the barrier layer 106 as shown in FIG. 9.

In other examples, the gate electrode 209 is formed in the process step (308) by etching the cap-layer 208 first and then depositing the gate metal over the cap-layer 208.

Several embodiments of the present invention have been described. Nevertheless, it will be understood that various modifications may be made without departing from the spirit and scope of the invention. Accordingly, other embodiments are within the scope of the following claims.

What is claimed is:

1. A semiconductor structure comprising:
a substrate;
a buffer layer disposed on a top surface of the substrate;
a channel layer disposed on a top surface of the buffer layer;
a barrier layer disposed on a top surface of the channel layer;
an etch-stop layer disposed on a top surface area of the barrier layer;
a cap-layer disposed on a top surface area of the etch-stop layer;
a source contact disposed on a first area of the barrier layer;
a drain contact disposed on a second area of the barrier layer;
a gate contact disposed on the cap-layer and between the source contact and the drain contact;
a dielectric layer disposed on areas of the etch-stop layer between the source contact and the gate contact and between the drain contact and the gate contact, respectively;
wherein the etch-stop layer is disposed on an area of the top surface of the barrier layer between the first area and the second area.

2. The semiconductor structure of claim 1, further comprising a gate dielectric layer disposed between a bottom surface of the gate contact and the top surface of the cap-layer.

3. The semiconductor structure of claim 1, wherein the buffer layer comprises a first III-nitride semiconductor, the channel layer comprises a second III-nitride semiconductor, the barrier layer comprises a third III-nitride semiconductor, the etch-stop layer comprises a fourth III-nitride semiconductor, and the cap layer comprises a fifth III-nitride semiconductor.

4. The semiconductor structure of claim 3, wherein the first, second, third, fourth, and fifth III-nitride semiconductors comprise one of AlGaN, AlN, GaN, InAlN, or combinations thereof.

5. The semiconductor structure of claim 3, wherein the third III-nitride semiconductor comprises a wider band-gap than the second III-nitride semiconductor.

6. The semiconductor structure of claim 5, wherein the third III-nitride semiconductor comprises one of AlGaN, or InAlN and wherein the AlGaN, or InAlN comprise an Aluminum composition in the range of zero and 35%.

7. The semiconductor structure of claim 1, wherein the barrier layer comprises a thickness in the range of 0.2 nm and 20 nm.

8. The semiconductor structure of claim 3, wherein the fourth III-nitride semiconductor comprises a higher Aluminum composition than the third III-nitride semiconductor.

9. The semiconductor structure of claim 1, wherein the etch-stop layer comprises a thickness in the range of 0.25 nm and 5 nm.

10. The semiconductor structure of claim 3, wherein the fifth III-nitride semiconductor comprises one of Mg-doped GaN or Mg-doped AlGaN, or Mg-doped InGaN with doping density in the range of 1E17/cm³ and 1E21/cm³.

11. The semiconductor structure of claim 3, wherein the fifth III-nitride semiconductor comprises InGaN having an Indium composition less than 30%.

12. The semiconductor structure of claim 1, wherein the cap-layer comprises a thickness in the range of 1 nm and 70 nm.

13. The semiconductor structure of claim 1, wherein the gate contact comprises one of Ni, Ti, TiN, W, WN, Pt, polysilicon, a conductive material, or combinations thereof.

14. The semiconductor structure of claim 1, wherein the dielectric layer comprises one of SiₓN_{y}, SiO₂, SiOₓN_{y}, Al₂O₃, or any other dielectric that is configured to induce electrons in the channel layer at an interface between the barrier layer and the channel layer underneath the dielectric layer.

15. The semiconductor structure of claim 1, wherein the source and drain contacts comprise one of Ti, Al, TiN, W, WN, Ni, Au, Mo, a conductive material, or combinations thereof.

16. The semiconductor structure of claim 1, wherein the source and the drain contacts are configured to form ohmic contacts to the channel layer though first and second recesses formed in the dielectric layer, respectively.

17. The semiconductor structure of claim 16, wherein a bottom surface of the source contact and a bottom surface of the drain contact are in contact with the barrier layer.

18. The semiconductor structure of claim 16, wherein a bottom surface of the source contact and a bottom surface of the drain contact are in contact with the etch-stop layer.

19. The semiconductor structure of claim 16, wherein a bottom surface of the source contact and a bottom surface of the drain contact are in contact with the channel layer.

20. The semiconductor structure of claim 16, wherein a first portion of a bottom surface of the source contact and a first portion of a bottom surface of the drain contact are in contact with the etch-stop layer and a second portion of the bottom surface of the source contact and a second portion of the bottom surface of the drain contact are in contact with the barrier layer.

21. The semiconductor structure of claim 16, wherein a first portion of a bottom surface of the source contact and a first portion of a bottom surface of the drain contact are in contact with the dielectric layer and a second portion of the bottom surface of the source contact and a second portion of the bottom surface of the drain contact are in contact with the barrier layer.

22. The semiconductor structure of claim 1, wherein the substrate comprises one of SiC, sapphire, free-standing GaN, polycrystalline AlN, or a multi-layer substrate.

23. The semiconductor structure of claim 1, wherein the gate contact is wider than the cap-layer.

24. The semiconductor structure of claim 2, wherein the gate dielectric layer is non-continuous.

25. The semiconductor structure of claim 1, further comprising a spacer layer disposed between the barrier layer and the etch-stop layer.

26. The semiconductor structure of claim 25, wherein a first portion of a bottom surface of the source contact and a first portion of a bottom surface of the drain contact are in contact with the spacer layer and a second portion of the bottom surface of the source contact and a second portion of the bottom surface of the drain contact are in contact with the barrier layer.

27. The semiconductor structure of claim 25, wherein a bottom surface of the source contact and a bottom surface of the drain contact are in contact with the spacer layer.

28. A method for forming a semiconductor structure comprising:
providing a substrate;
depositing a buffer layer on a top surface of the substrate;
depositing a channel layer on a top surface of the buffer layer;
depositing a barrier layer on a top surface of the channel layer;
depositing an etch-stop layer on a top surface area of the barrier layer;
depositing a cap-layer on a top surface area of the etch-stop layer;
forming a source contact on a first area of the barrier layer;
forming a drain contact on a second area of the barrier layer;
forming a gate contact on the cap-layer between the source contact and the drain contact;
depositing a dielectric layer on areas of the etch-stop layer between the source contact and the gate contact and between the drain contact and the gate contact;
wherein the etch-stop layer is deposited on an area of the top surface of the barrier layer between the first area and the second area.

29. The method of claim 28, further comprising depositing a spacer layer on a top surface of the barrier layer.

30. The method of claim 28, wherein the source contact and the drain contact are formed by first forming first and second recesses into the dielectric layer, then stopping on the etch-stop layer, then removing the etch-stop layer in the recesses to expose the barrier layer, and then depositing metal into the first and second recesses to form the source contact and the drain contact, respectively.

31. The method of claim 28, wherein the dielectric layer covers the etch-stop layer where the cap-layer is absent.
